(19) United States
(12) Patent Application Publication
(10) Pub. No.: US 2007/0072421 A1
(43) Pub. Date: Mar. 29, 2007

(54) Method to passivate defects in integrated circuits

(76) Inventors: Chintamani Palsule, Fort Collins, CO (US); Homayoon Haddad, Beaverton, OR (US); Yoshio Nishi, Los Altos, CA (US)

Correspondence Address: AVAGO TECHNOLOGIES, LTD., P.O. BOX 1920, DENVER, CO, 80201-1920, US

(21) Appl. No.: 11/234,922

(22) Filed: Sep. 26, 2005

(51) Int. Cl. H01L 21/302; H01L 21/00; H01L 21/44; H01L 21/461

(52) U.S. Cl. 438/689; 438/125; 438/669

(57) ABSTRACT

Defects in an integrated circuit are electrically passivated. A hydrogen diffusion blocking film is placed on the integrated circuit. Atomic hydrogen is implanted through the hydrogen diffusion blocking film. The integrated circuit is annealed so that the implanted atomic hydrogen diffuses towards locations where the defects are concentrated.

### BACKGROUND

In integrated circuits, defects at the silicon/oxide interfaces, can result in increased current leakage. When the defects have states in the middle of the silicon bandgap, the defects offer leakage paths for carriers that can increase current leakage in the integrated circuits. In order to decrease the current leakage, it is desirable to electrically passivate defects at the silicon/oxide interfaces. For example, defects can be electrically passivated by tying up the defects with atomic hydrogen. When the defects are tied up with atomic hydrogen, this removes the interface states and reduces leakage current.

For example, when processing wafers that contain integrated circuits, the wafers can be annealed in a forming gas (nitrogen/hydrogen) ambient or nitrogen ambient to electrically passivate the defects. However, when the wafer has been processed, various films present in dielectric stacks or metal stacks in the integrated circuits can getter hydrogen or block hydrogen diffusion. This can severely restrict the movement of hydrogen to silicon/oxide interfaces within the integrated circuits. For example, silicon nitride, which is typically used as a passivation layer in integrated circuit, can block hydrogen diffusion. The existence of films which getter hydrogen or block hydrogen diffusion significantly limits the efficiency of performing electrical passivation by annealing wafers in a forming gas ambient or a nitrogen ambient.

### SUMMARY OF THE INVENTION

In accordance with an embodiment of the present invention, defects in an integrated circuit are electrically passivated. A hydrogen diffusion blocking film is placed on the integrated circuit. Atomic hydrogen is implanted through the hydrogen diffusion blocking film. The integrated circuit is annealed so that the implanted atomic hydrogen diffuses towards locations where the defects are concentrated.

### BRIEF DESCRIPTION OF THE DRAWINGS

FIG. 1 shows a simplified illustration of a cross section of an integrated circuit.

FIG. 2 sets out processing actions performed to passivate defects in silicon/oxide interfaces in accordance with an embodiment of the present invention.

FIG. 3 illustrates an atomic hydrogen implant through a hydrogen diffusion blocking film in accordance with an embodiment of the present invention.

FIG. 4 illustrates results of an anneal performed to diffuse hydrogen to silicon/oxide interfaces within an integrated circuit in accordance with an embodiment of the present invention.

### DESCRIPTION OF THE EMBODIMENT

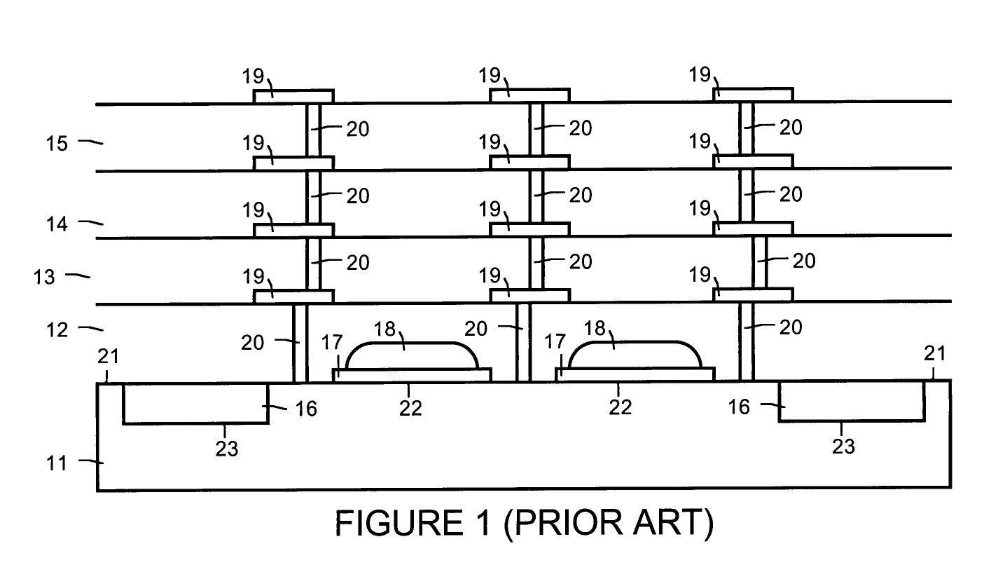

FIG. 1 shows a simplified illustration of a cross section of an integrated circuit. Field oxide regions 16 have been formed within a substrate 11. Polysilicon gates 18 gave been formed over gate oxide regions 17. Metal filled vias 20 through an inter-metal dielectric layer 12, an inter-metal dielectric layer 13, an inter-metal dielectric layer 14 and an inter-metal dielectric layer 15 connect metal regions 19 within various metal layers. The integrated circuit shown in FIG. 1 is illustrative of a wide variety of the types of structures and materials utilized that can be utilized in an integrated circuit.

Where silicon substrate 11 interfaces with oxide regions there tends to be a higher concentration of dangling bond defects. The dangling bond defects offer leakage paths for carriers, thus increasing current leakage in the integrated circuits. This higher concentration of defects exist, for example, in the integrated circuit shown in FIG. 1 at silicon/oxide interfaces. Specifically, defects occur in parts of silicon substrate 11 located below and within about 200 Angstroms (A) of interfaces 23 between field oxide regions 16 and substrate 11, in parts of silicon substrate 11 located immediately below and within about 200 Å of interfaces 22 between gate oxide regions 17 and substrate 11, and in parts of silicon substrate 11 located immediately below and within about 200 Å of interfaces 21 between inter-metal dielectric layer 12 and substrate 11.

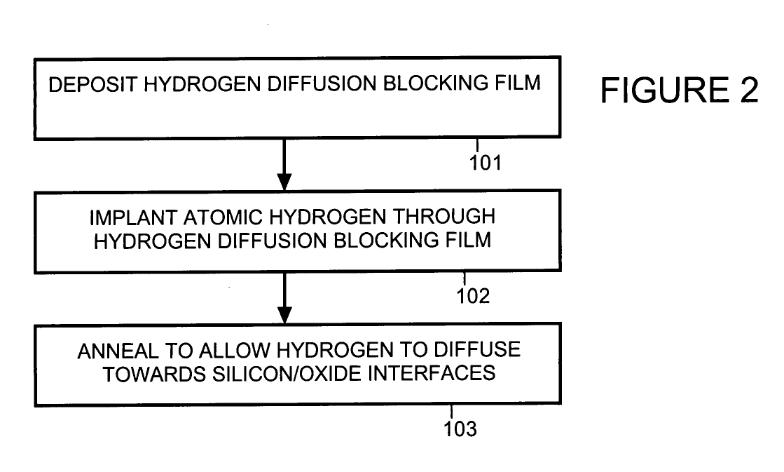

FIG. 2 sets out processing actions performed to electrically passivate defects in substrated 11 located at silicon/oxide interfaces 21, 22 and 23. In a block 101, a hydrogen diffusion blocking film is deposited.

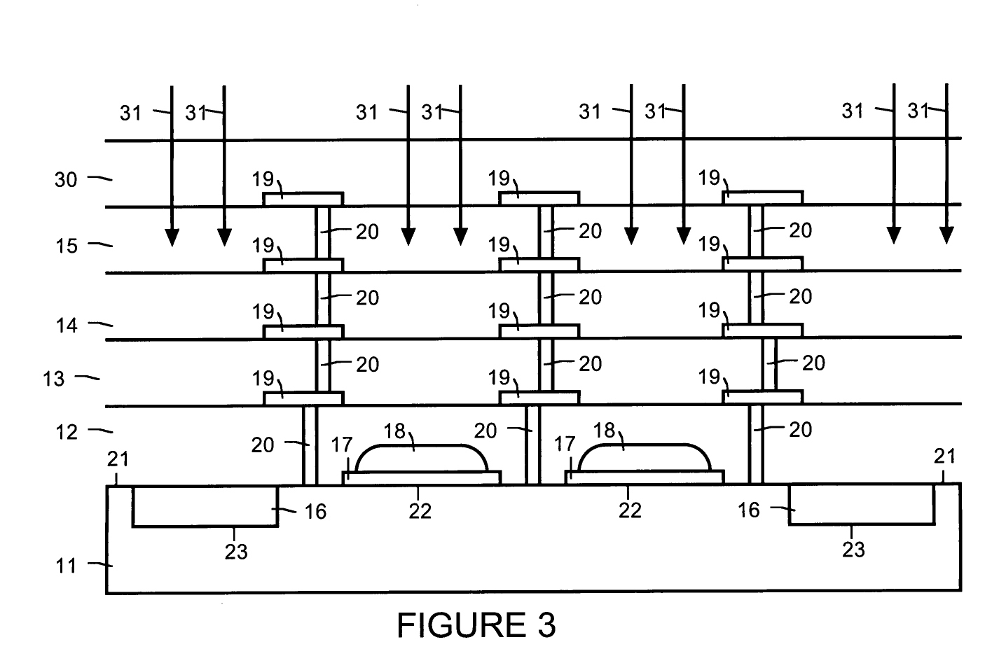

For example, FIG. 3 shows a hydrogen diffusion blocking film 30 deposited over inter-metal dielectric layer 15. For example, hydrogen diffusion blocking film 30 is composed of silicon nitride, silicon oxynitride or some other film capable of blocking hydrogen diffusion. The thickness of hydrogen diffusion blocking film 30 is sufficient to ensure that incorporated hydrogen does not diffuse into the ambient during subsequent high temperature processing. For example, hydrogen diffusion blocking film 30 is at least 5000 Angstroms thick.

In a block 102, shown in FIG. 2, atomic hydrogen is implanted through the hydrogen diffusion blocking film at implant energies sufficient to allow the atomic hydrogen to completely pass through the hydrogen diffusion blocking film.

In FIG. 3, arrows 31 represent atomic hydrogen being implanted through hydrogen diffusion blocking film 30. For example, the atomic hydrogen is implanted at a dose greater than 5e15/cm². For example, atomic hydrogen is implanted through hydrogen diffusion blocking film 30 at implant energy greater than 100 Kilo Electron volts (KeV).

In a block 103, an anneal is performed to allow hydrogen to diffuse towards silicon/oxide interfaces in the integrated circuit.

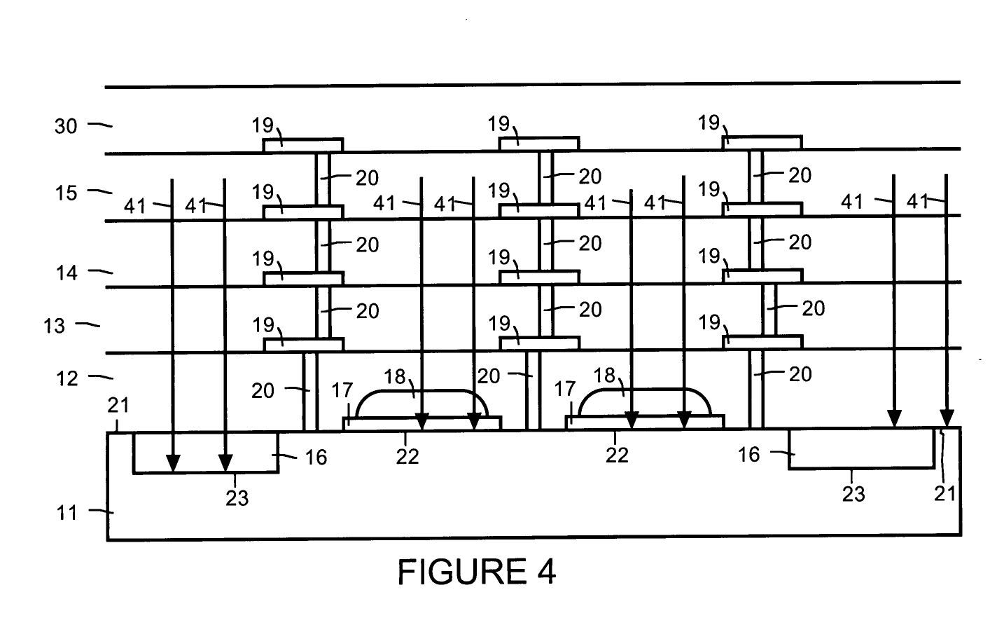

Hydrogen diffusion towards silicon/oxide interfaces is illustrated in FIG. 4 by arrows 41. As illustrated by arrows 41, during the anneal, hydrogen diffuses toward interfaces 23 between field oxide regions 16 and substrate 11, toward interfaces 22 between gate oxide regions 17 and substrate 11, and toward interfaces 21 between inter-metal dielectric layer 12 and substrate 11. The anneal is performed at a sufficiently high temperature for a sufficiently long time to allow hydrogen diffusion to reach silicon/oxide interfaces 21, 22 and 23. For example, the anneal is performed at a temperature greater than 380 degrees Centigrade for a time greater than 60 minutes.

Depending on the desired final processing steps for the integrated circuit, after completion of the anneal, the hydrogen diffusion blocking film can be removed or allowed to remain on the integrated circuit.

The use of an atomic hydrogen implant through a hydrogen diffusion blocking film, followed by an anneal, allows for efficient electrical passivation of defects at silicon/oxide interfaces. Passivation is effective even when there exist layers within the integrated circuit that normally hinder hydrogen diffusion. The improved electrical passivation leads to lower leakage currents in the integrated circuit.

The foregoing discussion discloses and describes merely exemplary methods and embodiments of the present invention. As will be understood by those familiar with the art, the invention may be embodied in other specific forms without departing from the spirit or essential characteristics thereof. Accordingly, the disclosure of the present invention is intended to be illustrative, but not limiting, of the scope of the invention, which is set forth in the following claims.

We claim:

1. A method for electrically passivating defects in an integrated circuit comprising:
placing a hydrogen diffusion blocking film on the integrated circuit;
implanting atomic hydrogen through the hydrogen diffusion blocking film; and,
annealing the integrated circuit so that the implanted atomic hydrogen diffuses towards locations where the defects are concentrated.

2. A method as in claim 1 wherein the defects are concentrated at silicon/oxide interfaces within the integrated circuit.

3. A method as in claim 1 wherein the hydrogen diffusion blocking film is composed silicon nitride.

4. A method as in claim 1 wherein the hydrogen diffusion blocking film is composed silicon oxynitride.

5. A method as in claim 1 wherein annealing is performed at a temperature greater than 380 degrees Centigrade for a time greater than 60 minutes.

6. A method as in claim 1 wherein implanting atomic hydrogen is performed at an implant energy greater than 100 Kilo Electron volts (KeV).

7. A method as in claim 1 wherein the atomic hydrogen is implanted at a dose greater than 5e15/cm².

8. A method for electrically passivating defects in an integrated circuit comprising:
implanting atomic hydrogen through a hydrogen diffusion blocking film; and,
annealing the integrated circuit at a temperature and for a duration sufficient so that the implanted atomic hydrogen diffuses towards locations where the defects are concentrated.

9. A method as in claim 8 wherein the defects are concentrated at silicon/oxide interfaces within the integrated circuit.

10. A method as in claim 8 wherein the hydrogen diffusion blocking film is composed silicon nitride.

11. A method as in claim 8 wherein the hydrogen diffusion blocking film is composed silicon oxynitride.

12. A method as in claim 8 wherein annealing is performed at a temperature greater than 380 degrees Centigrade for a time greater than 60 minutes.

13. A method as in claim 8 wherein implanting atomic hydrogen is performed at an implant energy greater than 100 Kilo Electron volts (KeV).

14. A method as in claim 8 wherein the atomic hydrogen is implanted at a dose greater than 5e15/cm².
